(19) United States
(12) Patent Application Publication
(10) Pub. No.: US 2024/0201582 A1
(43) Pub. Date: Jun. 20, 2024

(54) PATTERN FORMATION METHOD AND REPLICA TEMPLATE

(71) Applicant: Kioxia Corporation, Tokyo (JP)

(72) Inventor: Ryo KOBAYASHI, Kawasaki Kanagawa (JP)

(73) Assignee: Kioxia Corporation, Tokyo (JP)

(21) Appl. No.: 18/460,920

(22) Filed: Sep. 5, 2023

(30) Foreign Application Priority Data
Dec. 14, 2022 (JP) 2022-199745

(51) Int. Cl. G03F 7/00; B29C 59/02

(52) U.S. Cl. CPC G03F 7/0002; B29C 59/02; H10B 43/27

(57) ABSTRACT

A pattern formation method includes forming a hard mask layer on a first surface of a first substrate; exposing a second region of the first surface, with a first region of the first surface covered by the hard mask layer; forming a resist mask layer on the hard mask layer and on the second region; molding the resist mask layer by pressing a template against the resist mask layer; curing the resist mask layer; and forming a first recessed portion recessed below the first surface and a first protruding portion protruding beyond a bottom face of the first recessed portion.

### CROSS-REFERENCE TO RELATED APPLICATION (S)

This application is based upon and claims the benefit of priority from Japanese Patent Application No. 2022-199745, filed Dec. 14, 2022, the entire contents of which are incorporated herein by reference.

### FIELD

Embodiments described herein relate generally to a pattern formation method and a replica template.

### BACKGROUND

A fine pattern can sometimes be formed using nanoimprint lithography (NIL) related to a semiconductor device manufacturing method.

### DESCRIPTION OF THE DRAWINGS

FIG. 1 is a perspective schematic view illustrating a template structure example.

FIG. 2 is a sectional schematic view illustrating a template structure example.

FIG. 3 is an upper face schematic view showing an example of a layout of a device pattern formed on a mesa.

FIG. 4 is a sectional schematic view showing a device pattern layout example.

FIG. 5 is a sectional schematic view illustrating an example of a template manufacturing method in a case of a replica template.

FIG. 6 is a sectional schematic view illustrating an example of a template manufacturing method in a case of a replica template.

FIG. 7 is a sectional schematic view illustrating an example of a template manufacturing method in a case of a replica template.

FIG. 8 is a sectional schematic view illustrating an example of a template manufacturing method in a case of a replica template.

FIG. 9 is a sectional schematic view illustrating an example of a template manufacturing method in a case of a replica template.

FIG. 10 is a sectional schematic view illustrating an example of a template manufacturing method in a case of a replica template.

FIG. 11 is a sectional schematic view illustrating an example of a template manufacturing method in a case of a replica template.

FIG. 12 is a sectional schematic view illustrating an example of a template manufacturing method in a case of a replica template.

FIG. 13 is a sectional schematic view illustrating an example of a template manufacturing method in a case of a replica template.

FIG. 14 is a sectional schematic view illustrating an example of a template manufacturing method in a case of a replica template.

FIG. 15 is a sectional schematic view illustrating an example of a template manufacturing method in a case of a replica template.

FIG. 16 is a sectional schematic view illustrating an example of a template manufacturing method in a case of a replica template.

FIG. 17 is a sectional schematic view illustrating an example of a template manufacturing method in a case of a replica template.

FIG. 18 is a sectional schematic view illustrating an example of a template manufacturing method in a case of a replica template.

FIG. 19 is a sectional schematic view for comparing and describing an existing pattern formation method using NIL and a pattern formation method of an embodiment.

FIG. 20 is a sectional schematic view for comparing and describing an existing pattern formation method using NIL and the pattern formation method of the embodiment.

FIG. 21 is a sectional schematic view showing a semiconductor device structure example.

FIG. 22 is an X-Z sectional schematic view illustrating an example of a memory pillar structure.

FIG. 23 is a sectional schematic view illustrating an example of a semiconductor device manufacturing method.

FIG. 24 is a sectional schematic view illustrating an example of a semiconductor device manufacturing method.

FIG. 25 is a sectional schematic view illustrating an example of a semiconductor device manufacturing method.

FIG. 26 is a sectional schematic view illustrating an example of a semiconductor device manufacturing method.

FIG. 27 is a sectional schematic view illustrating an example of a semiconductor device manufacturing method.

FIG. 28 is a sectional schematic view illustrating an example of a semiconductor device manufacturing method.

FIG. 29 is a sectional schematic view illustrating an example of a semiconductor device manufacturing method.

FIG. 30 is a sectional schematic view illustrating an example of a semiconductor device manufacturing method.

FIG. 31 is a sectional schematic view illustrating an example of a semiconductor device manufacturing method.

FIG. 32 is a sectional schematic view illustrating an example of a semiconductor device manufacturing method.

### DETAILED DESCRIPTION

Embodiments provide formation of a desired pattern with high precision.

In general, according to one embodiment, a pattern formation method includes forming a hard mask layer on a first surface of a first substrate; exposing a second region of the first surface, with a first region of the first surface covered by the hard mask layer; forming a resist mask layer on the hard mask layer and on the second region; molding the resist mask layer by pressing a template against the resist mask layer; curing the resist mask layer; and forming a first recessed portion recessed below the first surface and a first protruding portion protruding beyond a bottom face of the first recessed portion.

Hereafter, an embodiment will be described with reference to the drawings. A relationship between a thickness and a planar dimension of each component shown in the drawings, a thickness ratio of each component, and the like, may differ from actuality. Also, in the embodiment, identical reference signs are allotted to substantially identical components, and a description thereof is omitted as appropriate.

### Template Structure Example

A pattern formation method in which NIL is used is such that a device pattern of an original plate called a template is pressed onto a layer of an imprinting material, such as an ultraviolet-curable resin, provided on a target object, and the layer is cured by irradiating with light such as ultraviolet light, whereby the device pattern is transferred to the imprinting material layer. For example, a master template, or a replica template manufactured using a master template, that forms a mold is suggested as a general template.

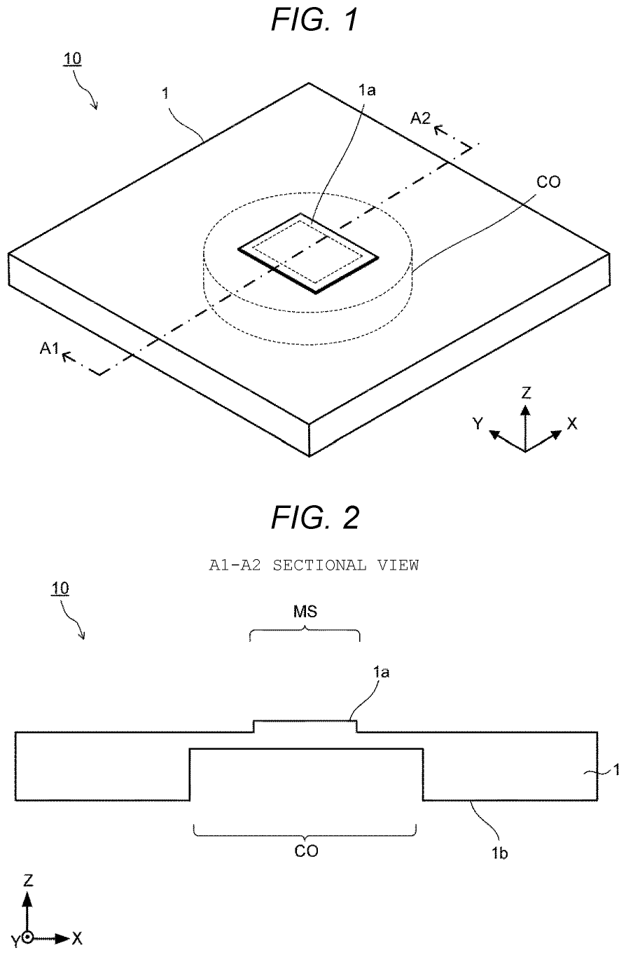

FIG. 1 is a perspective schematic view illustrating a template structure example. FIG. 2 is a sectional schematic view illustrating a template structure example. FIGS. 1 and 2 show an X axis, a Y axis perpendicular to the X axis, and a Z axis perpendicular to each of the X axis and the Y axis. FIG. 2 shows one portion of a cross-section along a line segment A1-A2 shown in FIG. 1.

As shown in FIGS. 1 and 2, a template 10 has a substrate 1 having a surface 1a including a mesa MS and a surface 1b including a recessed portion CO. The mesa MS is a portion on which a device pattern is formed. Although not particularly limited, a planar form of the mesa MS is, for example, a rectangular form. The surface 1a is a main face.

The substrate 1 includes, for example, quartz glass. The substrate 1 preferably allows the aforementioned light to pass through.

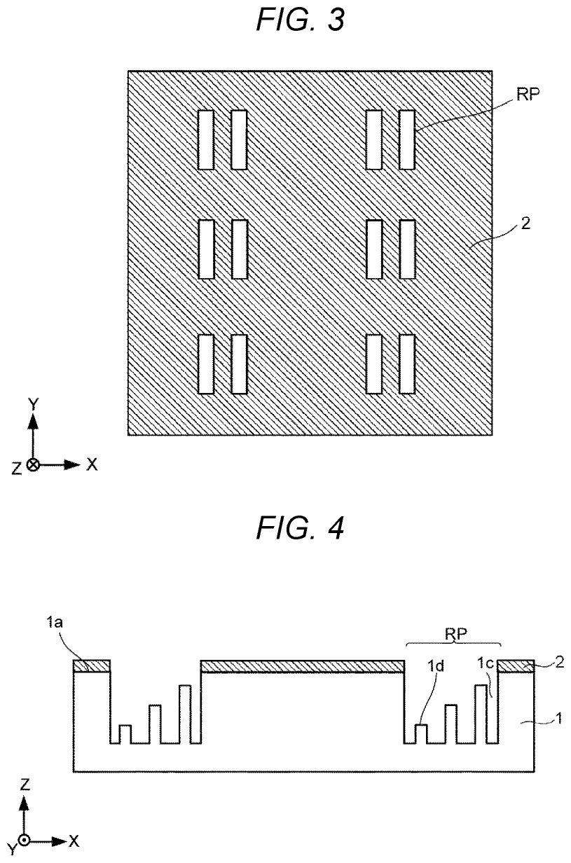

FIG. 3 is an upper face schematic view showing an example of a layout of a device pattern formed on the mesa MS. FIG. 4 is a sectional schematic view showing a device pattern layout example. FIG. 4 shows one portion of a cross-section including an X axis of the template 10 and a Z axis of the template 10. Herein, a replica template device pattern layout example is shown as one example.

In the case of a replica template, the template 10 has a replica pattern RP as a device pattern. The replica pattern RP has a recessed portion 1c, and a protruding portion 1d provided in the recessed portion 1c. The template 10 shown in FIG. 3 shows a multiple of the replica patterns RP, and each replica pattern RP has the recessed portion 1c and the protruding portion 1d. The recessed portion 1c is recessed below the surface 1a. The protruding portion 1d protrudes in the Z axis direction from a bottom face of the recessed portion 1c. The protruding portion 1d is, for example, a pillar. FIG. 4 shows a multiple of the protruding portions 1d having differing heights with respect to the bottom face of the recessed portion 1c. An upper face of the protruding portion 1d having the greatest height with respect to the bottom face of the recessed portion 1c may be provided below the surface 1a.

As shown in FIGS. 3 and 4, the template 10 may have a hard mask layer 2 on the surface 1a. The hard mask layer 2 is used when forming the replica pattern RP. The hard mask layer 2 encloses the replica pattern RP on the surface 1a. The hard mask layer 2 contains, for example, chrome.

### Template Manufacturing Method Example

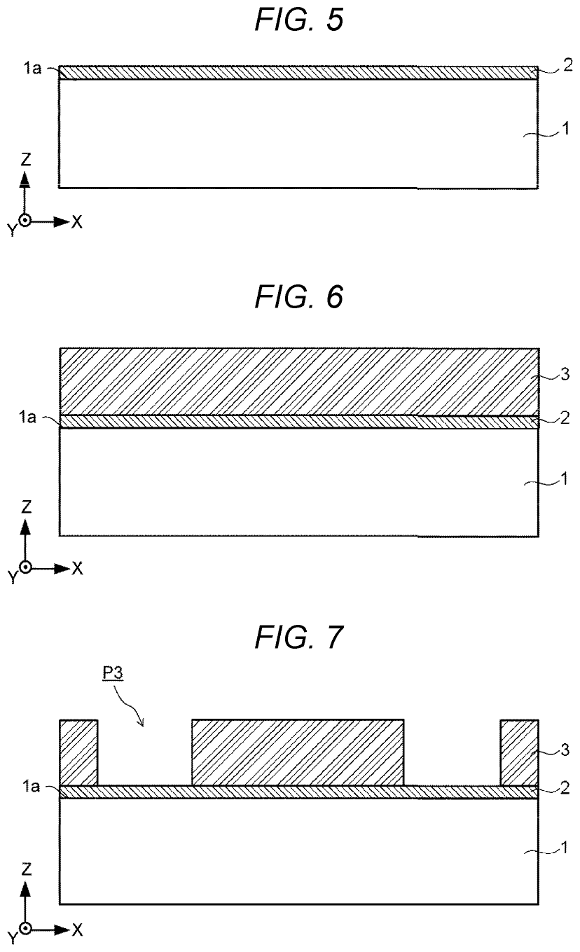

FIGS. 5 to 18 are examples of sectional schematic views illustrating a method of manufacturing the template 10 in the case of a replica template, and show one portion of an X-Z cross-section of the substrate 1.

Firstly, as shown in FIG. 5, the hard mask layer 2 is formed on the surface 1a. The hard mask layer 2 contains, for example, chrome. The hard mask layer 2 may be formed using, for example, sputtering or atomic layer deposition (ALD).

Next, as shown in FIG. 6, a resist mask layer 3 is formed on the hard mask layer 2. The resist mask layer 3 may be formed by supplying an uncured resin using, for example, a spin coating method or an application method. Also, the resist mask layer 3 may also be formed by dripping an uncured resin from a dispenser using an ink jet method.

Next, as shown in FIG. 7, the resist mask layer 3 is selectively cured using photolithography, and an uncured portion is removed, thereby forming a resist pattern P3 that causes one portion of the hard mask layer 2 to be exposed. Not being limited to this, the resist pattern P3 may also be formed using NIL or an electron beam.

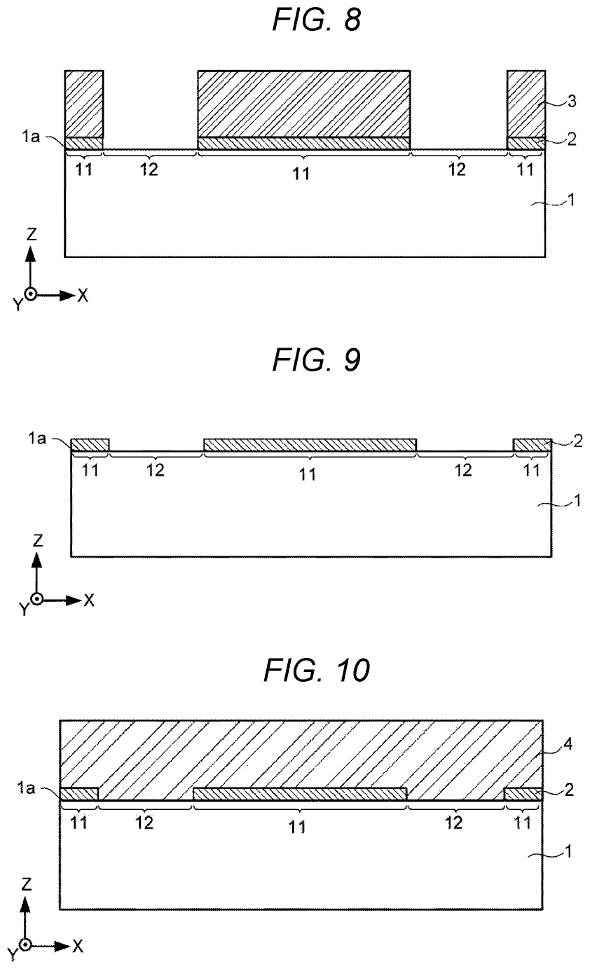

Next, as shown in FIG. 8, the hard mask layer 2 is partially etched, and the exposed portion of the hard mask layer 2 is removed, whereby a region 12 of the surface 1a is exposed, with a region 11 of the surface 1a still covered by the hard mask layer 2. The region 11 is a region in which the replica pattern RP is not subsequently formed. The region 12 is a region in which the replica pattern RP is subsequently formed. The hard mask layer 2 may be partially removed using, for example, a dry etching.

Next, as shown in FIG. 9, the resist mask layer 3 is removed with the hard mask layer 2 still remaining. The resist mask layer 3 may be removed using, for example, RIE.

Next, as shown in FIG. 10, a resist mask layer 4 is formed on the hard mask layer 2 and on the region 12. The resist mask layer 4 may be formed by supplying an uncured resin using, for example, a spin coating method or an application method. Also, the resist mask layer 4 may also be formed by dripping an uncured resin from a dispenser using an ink jet method.

Next, the resist mask layer 4 is molded. The resist mask layer 4 may be molded using, for example, NIL.

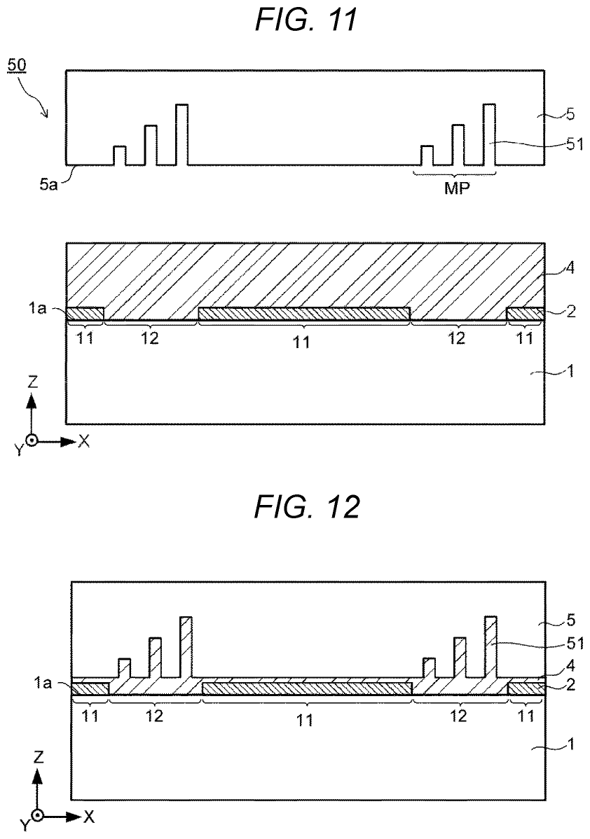

When using NIL, firstly, a master template 50 is prepared as shown in FIG. 11. FIG. 11 shows one portion of an X-Z cross-section of the master template 50. The master template 50 has a substrate 5, and has a master pattern MP on a surface 5a of the substrate 5. The substrate 5 includes, for example, quartz glass. The substrate 5 preferably allows the aforementioned light to pass through. Regarding a remaining description of the substrate 5, the description of the template 10 may be referred to as appropriate.

The master pattern MP has a recessed portion 51 recessed below, for example, the surface 5a. The recessed portion 51 is, for example, a hole. FIG. 11 shows, as one example, a multiple of the recessed portions 51 whose depths from the surface 5a differ. The master template 50 is disposed above the resist mask layer 4.

Next, as shown in FIG. 12, the resist mask layer 4 is molded by the master template 50 being pressed against the resist mask layer 4. At this time, the recessed portion 51 is filled with one portion of the resist mask layer 4, and another portion of the resist mask layer 4 remains between the master template 50 and the hard mask layer 2. Subsequently, with the master template 50 still pressed against the resist mask layer 4, the resist mask layer 4 is cured by irradiating the resist mask layer 4 with light.

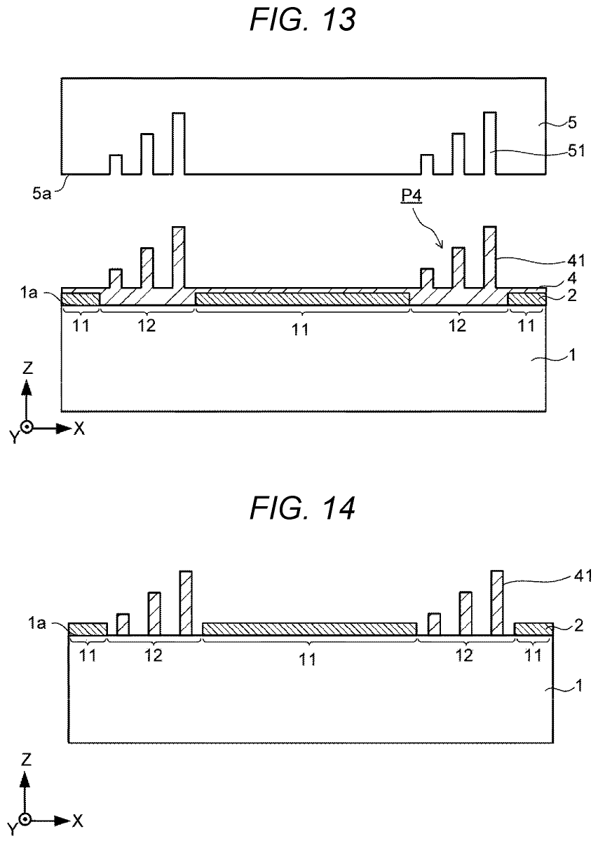

Next, as shown in FIG. 13, the master template 50 is removed from the resist mask layer 4. The cured resist mask layer 4 has a resist pattern P4, which is a pattern transferred from the master pattern MP of the master template 50. The resist pattern P4 has at least one protruding portion 41. The protruding portion 41 is, for example, a pillar. When the master pattern MP has a multiple of the recessed portions 51 whose depths from the surface 5a differ, the resist pattern P4 has a multiple of the protruding portions 41 whose heights from the surface 1a differ.

Next, as shown in FIG. 14, the region 12 is partially exposed, with the region 11 of the surface 1a still covered by the hard mask layer 2, by carrying out an anisotropic etching of the resist mask layer 4 after curing in the Z-axis direction. When the resist pattern P4 has the protruding portion 41, at least one portion of the protruding portion 41 remains. The resist mask layer 4 may be etched using, for example, oxygen plasma.

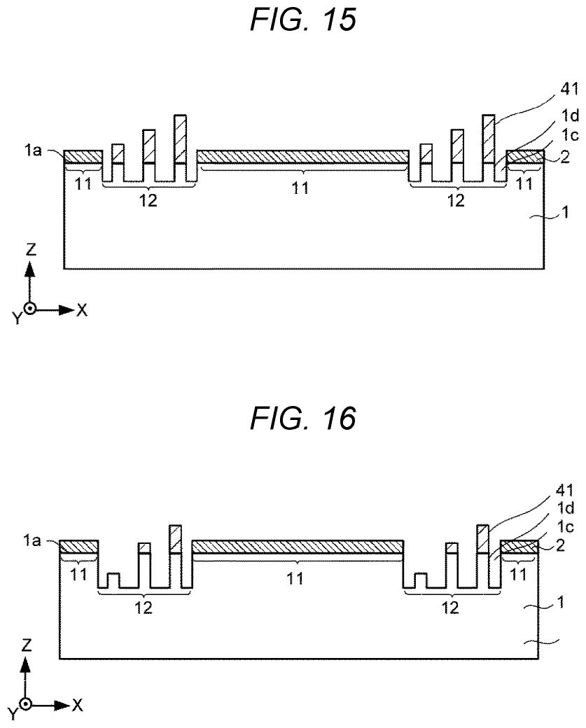

Next, as shown in FIG. 15, the recessed portion 1c and the protruding portion 1d are formed by carrying out an anisotropic etching of the region 12 of the substrate 1 in the Z-axis direction using the hard mask layer 2 and the resist mask layer 4. The substrate 1 may be partially removed using, for example, RIE.

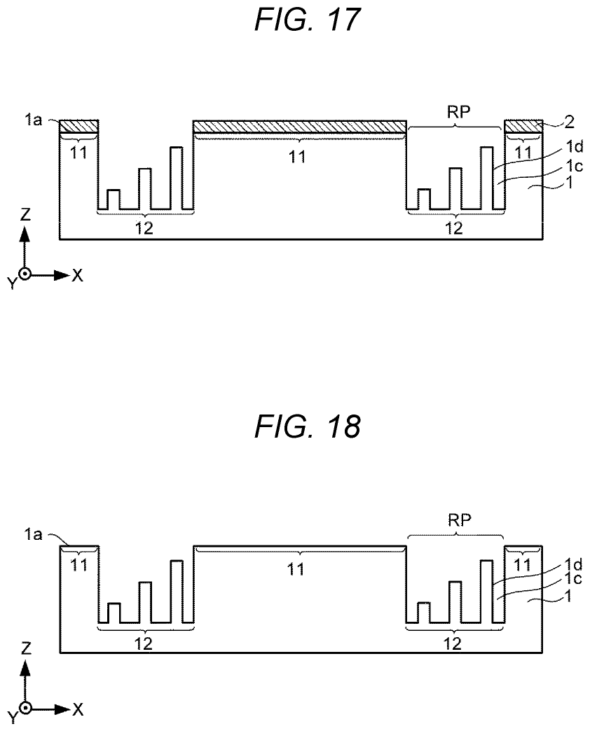

When forming a multiple of the protruding portions 1d having differing heights, the recessed portion 1c is processed more deeply by further continuing the etching, as shown in FIG. 16. By continuing the etching further still, the recessed portion 1c is processed more deeply, as shown in FIG. 17. The replica pattern RP having the recessed portion 1c and the protruding portion 1d is formed by the heretofore described etching. At this time, the recessed portion 1c and the protruding portion 1d may be processed by etching until the upper faces of all the protruding portions 1d are positioned below the surface 1a, as shown in FIG. 16, or the upper face of one portion of the protruding portions 1d may be of the same height as the surface 1a. The processed protruding portion 1d has a form that is an inversion of the recessed portion 51 of the master pattern MP.

Next, the hard mask layer 2 may be removed, as shown in FIG. 18. Not being limited to this, the hard mask layer 2 may remain without being removed after the formation of the replica pattern RP.

The above is a description of an example of a method of manufacturing the template 10 in the case of a replica template.

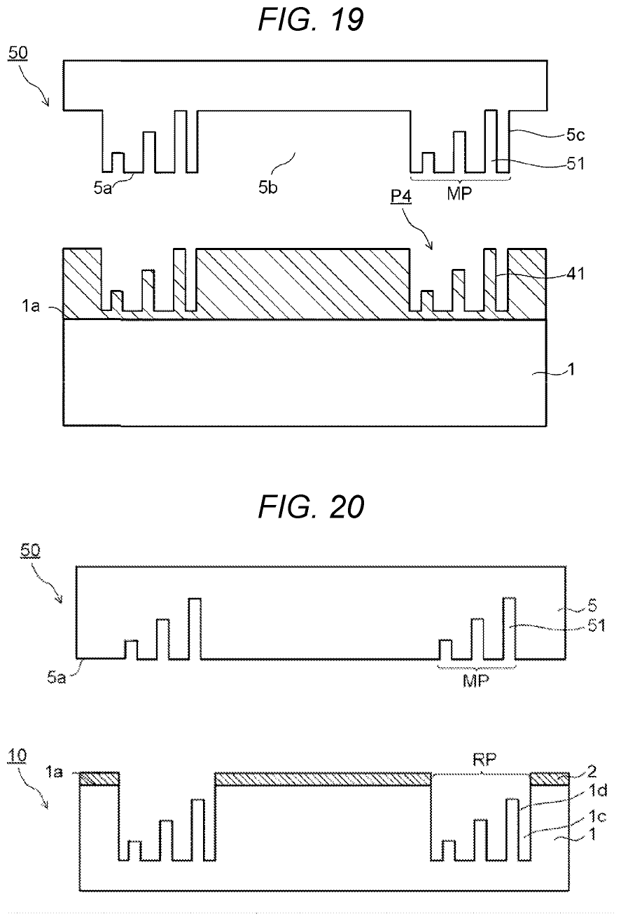

FIGS. 19 and 20 are sectional schematic views for comparing and describing an existing pattern formation method using NIL and the pattern formation method of the embodiment. The existing pattern formation method using NIL is such that when forming a replica template using the master template 50, the replica pattern RP needs to have a form that is an inversion of the master pattern MP on a replica template to which a pattern is transferred from the master template 50. Because of this, a recessed portion 5b having a form that is an inversion of a region in which the replica pattern RP is not formed is formed in a position opposing the region, and furthermore, when forming the protruding portion 1d as the replica pattern RP, a protruding portion 5c that protrudes farther than the recessed portion 5b is formed in the master template 50. When a height of the protruding portion 5c with respect to a bottom face of the recessed portion 5b increases at this time, a filling of the recessed portion 5b with a resist material is liable to be insufficient when pressing the master template 50 against the resist mask layer 4 before curing. This is a cause of the form of the resist pattern P4 in the resist mask layer 4 changing from a desired form, which is a cause of the form of the replica pattern RP changing from a desired form. Therefore, pattern formation accuracy decreases.

In response to this, the pattern formation method of the embodiment is such that owing to the substrate 1 being processed using the hard mask layer 2 and the resist mask layer 4, forming the recessed portion 5b and protruding portion 5c having inverted forms becomes unnecessary, as shown in FIG. 20. At this time, the master template 50 does not have a protruding portion having a form that is an inversion of the recessed portion 1c. Because of this, a change in the form of the replica pattern RP due to insufficient filling with a resist material can be restricted. Therefore, a desired pattern can be formed with high accuracy.

### Semiconductor Device Manufacturing Method Example

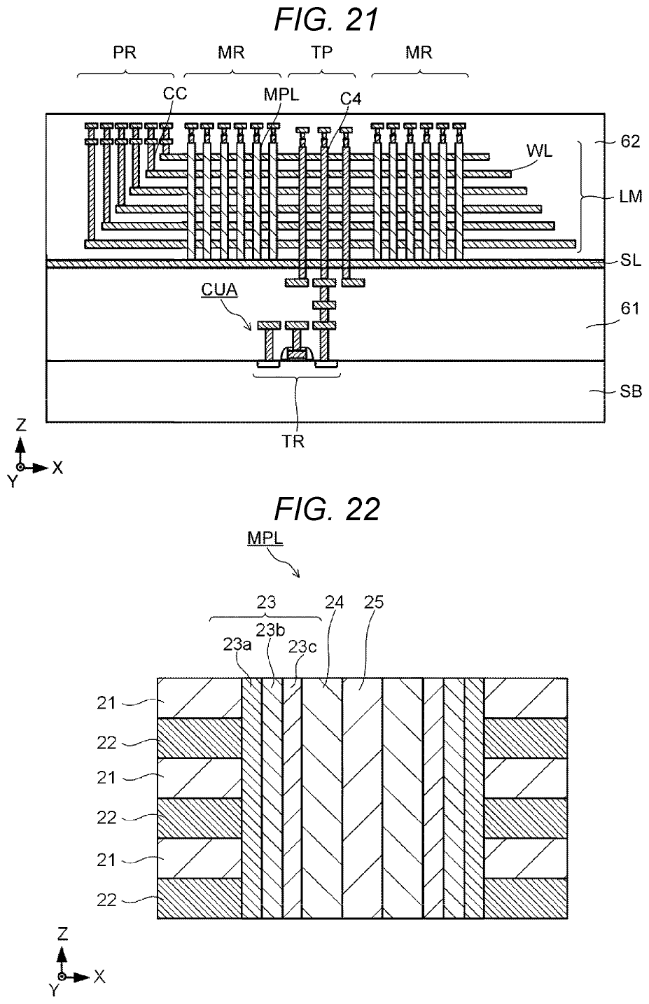

A description will be given of an example of a method of manufacturing a semiconductor device that may be manufactured using a pattern formation method in which a replica template formed using the pattern formation method of the embodiment is used. FIG. 21 is a sectional schematic view showing a semiconductor device structure example, and shows one portion of an X-Z cross-section of a substrate SB. Herein, as one example, an example of a three-dimensional layered semiconductor storage device will be described.

As shown in FIG. 21, the semiconductor device has, in order, a peripheral circuit CUA, a source line SL, and a layered body LM on the substrate SB, which is a silicon substrate or the like. The peripheral circuit CUA has a transistor TR formed on the substrate SB, and controls an operation of a memory cell to be described hereafter. The peripheral circuit CUA is covered by, for example, an insulating film 61. The insulating film 61 includes silicon and oxygen. The source line SL is provided on the insulating film 61, and is formed using a material such as a conductive polysilicon.

The layered body LM on the source line SL has a multiple of stacked word lines WL. The word line WL includes a metal material such as tungsten or molybdenum. The number of stacked word lines WL is not particularly limited.

The layered body LM has a memory region MR, a contact region PR, and a penetrating contact region TP. The memory region MR has a multiple of memory pillars MPL. The contact region PR has a multiple of contacts CC. The penetrating contact region TP has a multiple of contacts C4. The layered body LM is covered by an insulating film 62 such as a silicon oxide film. Each of the multiple of memory pillars MPL penetrates the layered body LM in the Z-axis direction to reach the source line SL.

FIG. 22 is an X-Z sectional schematic view illustrating an example of a structure of the memory pillar MPL. The memory pillar MPL shown in FIG. 22 has an insulating layer 21, a conductive layer 22, a memory layer 23, a semiconductor layer 24, and a core insulating body 25.

The insulating layer 21 and the conductive layer 22 form the layered body LM. A multiple of the conductive layers 22 form the word lines WL of the semiconductor storage device. The insulating layer 21 includes, for example, silicon and oxygen. The conductive layer 22 includes a metal material.

The memory layer 23 has a block insulating film 23a, a charge storage film 23b, and a tunnel insulating film 23c. The block insulating film 23a and the tunnel insulating film 23c include, for example, silicon and oxygen. The charge storage film 23b includes, for example, silicon and nitrogen.

The semiconductor layer 24 penetrates the layered body LM in the Z-axis direction. The semiconductor layer 24 is electrically connected to the source line SL. An outer periphery of the semiconductor layer 24 is covered by the memory layer 23. The semiconductor layer 24 includes, for example, polysilicon or amorphous silicon.

The core insulating body 25 is provided on an inner side of the semiconductor layer 24. The core insulating body 25 extends along the semiconductor layer 24. The core insulating body 25 includes, for example, silicon oxide.

An intersection point of the memory pillar MPL and the conductive layer 22 functions as a memory transistor. A memory transistor forms a memory cell of a memory cell array. By a predetermined voltage being applied from the word line WL to a memory cell positioned at the same height, a charge is accumulated in the charge storage film 23b of the memory cell, or a charge is extracted from the charge storage film 23b, whereby a write and a read of data onto and from the memory cell can be carried out. Data read from the memory cell are transmitted to an unshown sense amplifier via a plug, upper layer wiring, or the like above the memory pillar MPL.

Each of the multiple of contacts CC reaches a position at a depth of one word line WL of the multiple of word lines WL included in the layered body LM, and is connected to the word line WL. Also, each of the multiple of contacts CC is connected to the multiple of contacts C4 via upper layer wiring and a plug.

The multiple of contacts C4 penetrate the layered body LM and the source line SL, reaching the insulating film 61 below the layered body LM. A lower end portion of each of the multiple of contacts C4 is connected to the transistor TR of the peripheral circuit CUA via a conductive body such as lower layer wiring, a via, or a conductor. According to the heretofore described configuration, a predetermined voltage is applied from the peripheral circuit CUA to each memory cell via the contact C4 and the contact CC, whereby the memory cell can be electrically operated.

The heretofore described three-dimensional layered semiconductor storage device can be formed easily using NIL in which a replica template formed using, for example, the pattern formation method of the embodiment is used. As a structure for forming a three-dimensional layered semiconductor storage device, there is, for example, a dual damascene structure DD, wherein a via that electrically connects the contact C4 and the peripheral circuit CUA and wiring are formed at one time, a multiple of contacts CC that reach one each of word lines WL at differing depths of the layered body LM, and the like.

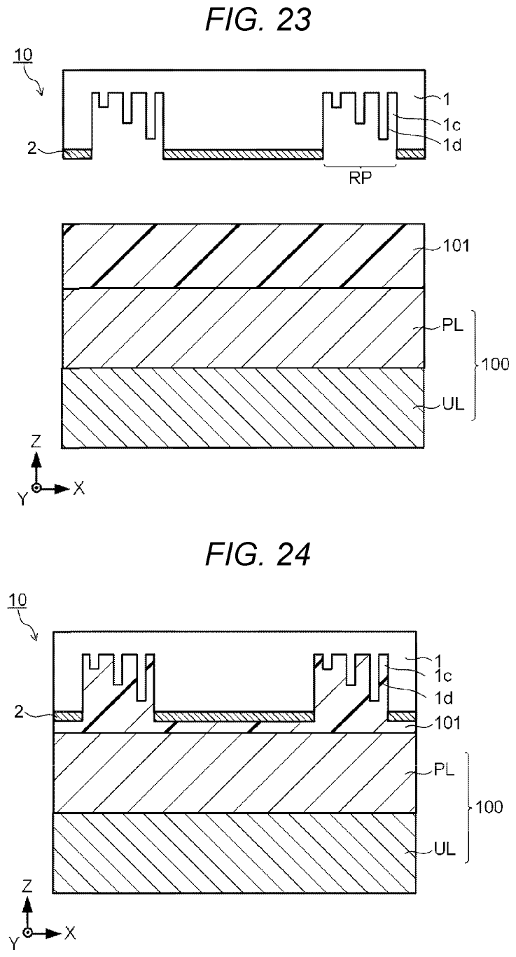

Next, a semiconductor device manufacturing process will be described. FIGS. 23 to 32 are sectional schematic views illustrating an example of a semiconductor device manufacturing method, and show one portion of an X-Z cross-section of a target object 100. A process shown in FIGS. 23 to 32 is also a pattern formation method in which the heretofore described replica template is used.

As shown in FIG. 23, a resist mask layer 101 is formed on the target object 100. The target object 100 has an underlayer UL, and a processing layer PL on the underlayer UL. The underlayer UL is, for example, the insulating film 61 covering the peripheral circuit CUA in the semiconductor device shown in FIG. 21, the source line SL formed on the insulating film 61, and the like. The processing layer PL is, for example, a multilayer film wherein a multiple of nitride layers and oxide layers are stacked alternately. The processing layer PL is such that the nitride layers are subsequently replaced with conductive layers such as tungsten layers, forming the layered body LM.

The resist mask layer 101 may be formed by supplying a resist material onto the processing layer PL using, for example, a spin coating method or an application method. The resist mask layer 101 is formed in such a way as to cover a whole of a region on the processing layer PL to which, for example, the replica pattern RP of the template 10 is to be transferred. A region to which the replica pattern RP of the template 10 is not to be transferred is covered by the hard mask layer 2. At this stage, the resist mask layer 101 is in an uncured state.

As the replica pattern RP of the template 10 is to be transferred to the resist mask layer 101, the template 10 is caused to oppose the resist mask layer 101 with a surface on which the replica pattern RP is formed facing the processing layer PL side.

Next, as shown in FIG. 24, the protruding portion 1d of the template 10 is pressed against the resist mask layer 101 on the processing layer PL. At this time, a gap is formed between the protruding portion 1d that protrudes farthest and the processing layer PL in order that the mesa MS of the template 10 does not come into contact with the processing layer PL.

Owing to this state being maintained for a predetermined time, one portion of the resist mask layer 101 fills the recessed portion 1c of the template 10. Subsequently, with the template 10 still pressed against the resist mask layer 101, the resist mask layer 101 is irradiated with light such as ultraviolet light, which is caused to pass through the template 10. By so doing, the resist mask layer 101 is cured.

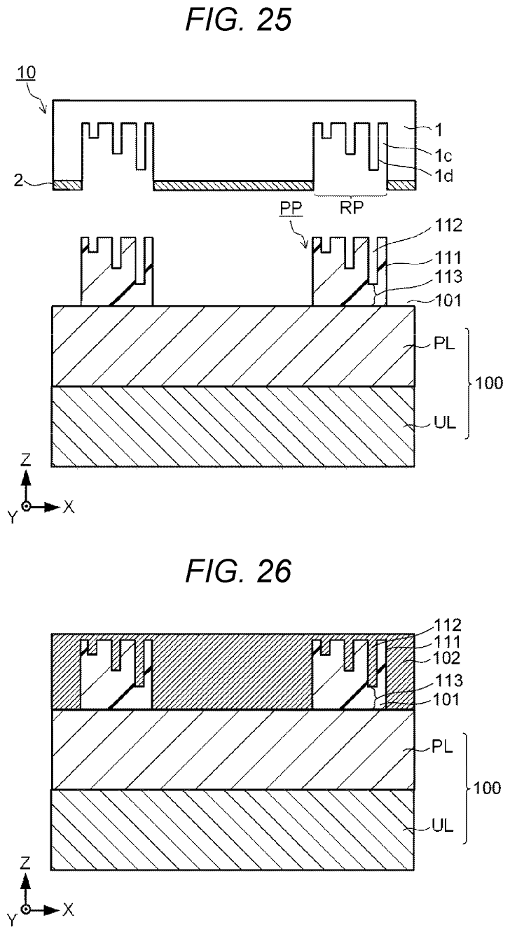

Next, as shown in FIG. 25, the template 10 is removed from the resist mask layer 101. The resist mask layer 101 after curing has a multiple of contact patterns PP.

The multiple of contact patterns PP are the transferred replica pattern RP of the template 10. The multiple of contact patterns PP are disposed separated from each other, and each has a protruding portion 111, which is the transferred recessed portion 1c of the template 10, and a multiple of recessed portions 112, which are the transferred protruding portion 1d of the template 10. The recessed portion 112 is, for example, a hole.

As the resist mask layer 101 is cured in a state wherein a gap is provided between the template 10 and the processing layer PL, the resist mask layer 101 has a remaining resist portion 113 on a bottom portion of the deepest recessed portion 1c of the recessed portions 1c.

Existing photolithography is such that forming a resist pattern having a multiple of patterns of differing depths in a resist film at one time is difficult. Because of this, a process wherein, for example, resist film formation, exposure and development, and processing film processing are repeated several times is needed.

As opposed to this, a pattern formation method in which the template 10 of the embodiment is used is such that a multiple of recessed portions of differing depths in the resist mask layer 101 can be formed in the resist mask layer 101 in one imprinting process.

Next, as shown in FIG. 26, a resist mask layer 102 that covers the resist mask layer 101 is formed. The resist mask layer 102 is a photosensitive positive resist film used in photolithography and the like, and may be formed by applying a positive resist material onto the resist mask layer 101 using, for example, a spin coating method or an application method.

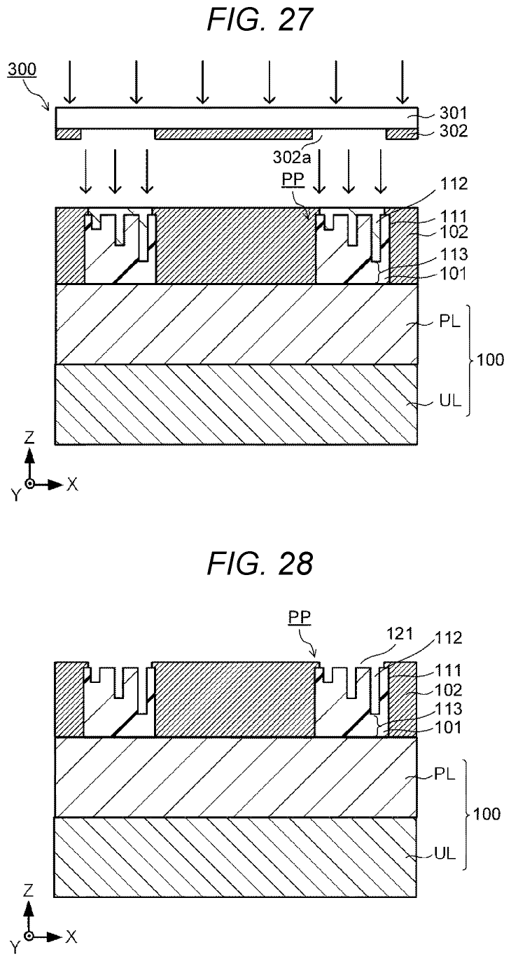

Next, as one portion of the resist mask layer 102 is to be exposed, a photomask 300 is disposed opposing the resist mask layer 102, as shown in FIG. 27. The photomask 300 has a light-transmitting substrate 301 and a light-blocking layer 302.

The light-blocking layer 302 has a multiple of apertures 302a. The multiple of apertures 302a are disposed in positions coinciding vertically with the multiple of contact patterns PP formed in the resist mask layer 101 on the processing layer PL. The multiple of apertures 302a are formed to be larger than a region in which the multiple of contact patterns PP are formed, and are disposed in such a way that a whole of each contact pattern PP fits in a position below the aperture 302a.

In a state wherein the photomask 300 is caused to oppose the resist mask layer 102, the resist mask layer 102 is irradiated with an exposure light such as ultraviolet light, which is caused to pass through the aperture 302a of the photomask 300. By so doing, a portion that covers the multiple of contact patterns PP of the resist mask layer 102 covering the resist mask layer 101 is exposed.

Next, the resist mask layer 102 having an aperture 121 in a position coinciding with the contact pattern PP of the resist mask layer 101 is formed by developing the partially exposed resist mask layer 102, as shown in FIG. 28. By so doing, the contact pattern PP of the resist mask layer 101 previously covered by the resist mask layer 102 is exposed in the aperture 121 of the resist mask layer 102.

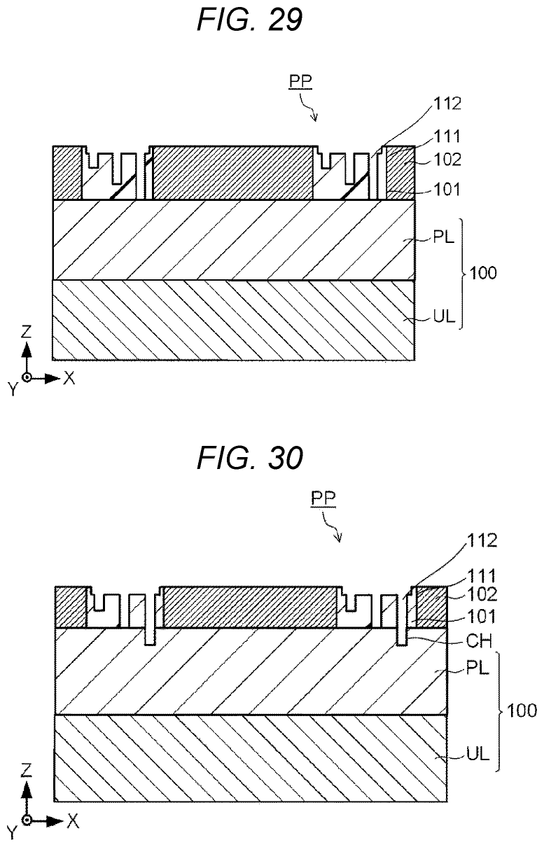

Next, as shown in FIG. 29, the remaining resist portion 113 on the bottom portion of the deepest recessed portion 112 is removed using, for example, oxygen plasma. By so doing, an upper face of the processing layer PL is exposed in the bottom portion of the deepest recessed portion 112. Also, film thicknesses of the resist mask layer 101 and the resist mask layer 102 decrease overall.

Next, as shown in FIG. 30, the processing layer PL is processed through the resist mask layer 101 and the resist mask layer 102. By so doing, the portion of the processing layer PL exposed in the resist mask layer 101 is removed, and a contact hole CH, which is the transferred deepest recessed portion 112, is formed.

Furthermore, the film thickness of the resist mask layer 101 is reduced using oxygen plasma or the like, whereby the remaining resist portion 113 on a bottom portion of the recessed portion 112 neighboring the deepest recessed portion 112 is removed, and an upper face of another portion of the processing layer PL is newly exposed. At this time, the film thickness of the resist mask layer 102 also decreases together with that of the resist mask layer 101.

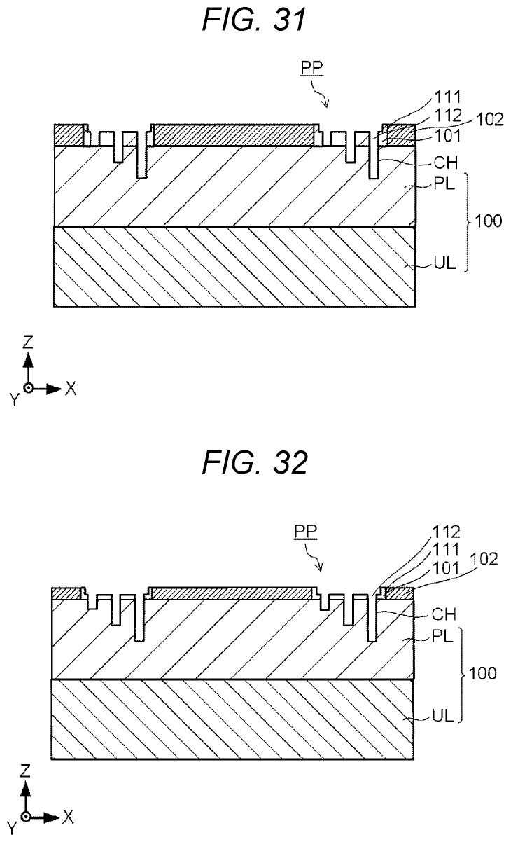

As shown in FIG. 31, the processing of the processing layer PL through the resist mask layer 101 and the resist mask layer 102 is further continued. By so doing, the upper face of the other portion of the processing layer PL newly exposed in the resist mask layer 101 is removed, and a new contact hole CH is formed. The existing contact hole CH in the processing layer PL becomes deeper still.

Also, the film thicknesses of the resist mask layer 101 and the resist mask layer 102 are reduced using oxygen plasma or the like, whereby the processing layer PL is newly exposed in the bottom portion of the recessed portion 112 neighboring the newly formed contact hole CH.

As shown in FIG. 32, the processing of the processing layer PL through the resist mask layer 101 and the resist mask layer 102, and the reduction of the film thicknesses of the resist mask layer 101 and the resist mask layer 102 using oxygen plasma or the like, are further continued. By so doing, the upper face of the other portion of the processing layer PL newly exposed in the resist mask layer 101 is removed, and a new contact hole CH is formed. The multiple of contact holes CH in the processing layer PL become deeper still.

Subsequently, the remaining resist mask layer 101 and resist mask layer 102 are removed. Thus, the pattern formation process in which the template 10 is used ends.

The heretofore described imprinting process is such that, for example, when the angular protruding portion 1d of the template 10 is transferred to the resist mask layer 101, the protruding portion 1d may be transferred to a form wherein a corner portion is rounded. Also, when forming the multiple of contact holes CH in the processing layer PL using the resist mask layer 101, a corner portion of the contact hole CH may be processed into a form that is further rounded.

Subsequently, the memory pillar MPL that causes a memory cell to be formed is formed among the multiple of contact regions PR formed in the processing layer PL. Also, a replacement process of replacing the silicon nitride layers of the processing layer PL having a multilayer structure with the word lines WL, which are tungsten layers or the like, is carried out, forming the layered body LM wherein the multiple of word lines WL and the multiple of insulating layers are alternately stacked.

Also, side walls of the multiple of contact holes CH formed using the template 10 are covered with an insulating layer, and an inner side of the insulating layer is filled with a metal layer, whereby the multiple of contacts CC connected one each to the word lines WL of differing depths are formed.

As heretofore described, the contact hole CH formed in the layered body LM may be such that, for example, the corner portion is of a rounded form owing to the heretofore described process. This means that when embedding a metal layer inside the contact hole CH and causing the metal layer to function as the contact CC, a power concentration, or the like, caused by the contact CC having an acute-angled portion can be restricted.

The above is a description of an example of a semiconductor device manufacturing method. The semiconductor device manufacturing method example of the embodiment is such that by using a replica template formed using the heretofore described pattern formation method, a complex pattern having, for example, a multiple of recessed portions of differing depths can be formed with high accuracy.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern formation method, comprising:
forming a hard mask layer on a first surface of a first substrate;
exposing a second region of the first surface, with a first region of the first surface covered by the hard mask layer;
forming a resist mask layer on the hard mask layer and on the second region;
molding the resist mask layer by pressing a template against the resist mask layer;
curing the resist mask layer; and
forming a first recessed portion recessed below the first surface and a first protruding portion protruding beyond a bottom face of the first recessed portion.

2. The pattern formation method according to claim 1, wherein the first recessed portion and the first protruding portion form a pattern of a replica template configured for nanoimprint lithography.

3. The pattern formation method according to claim 1, further comprising:
forming the first recessed portion and a multiple of the first protruding portions having differing heights by partially etching the second region using the hard mask layer and the resist mask layer.

4. An apparatus for forming a pattern, comprising:
a replica template including a first substrate; and
a master template including a second substrate;
wherein the first substrate has a first surface, a first recessed portion recessed below the first surface, and a first protruding portion protruding beyond a bottom face of the first recessed portion,
wherein the second substrate has a second surface and a second recessed portion recessed below the second surface,
wherein the first protruding portion has a form that is an inversion of the second recessed portion, and
wherein the second substrate does not have a protruding portion that has a form that is an inversion of the first recessed portion.

5. The replica template according to claim 4, wherein the first substrate has a multiple of the first protruding portions having different heights.

6. The pattern formation method according to claim 1, wherein the step of exposing a second region of the first surface further comprises partially etching the hard mask layer.

7. The pattern formation method according to claim 1, wherein the step of forming a first recessed portion recessed below the first surface and a first protruding portion protruding beyond a bottom face of the first recessed portion further comprises partially etching the second region using the hard mask layer and the resist mask layer.
